(19) United States
(12) Patent Application Publication
(10) Pub. No.: US 2025/0022836 A1
(43) Pub. Date: Jan. 16, 2025

(54) APPARATUS AND METHOD FOR PARTIALLY FLATTENING A SUBSTRATE, BONDING AN ELECTRONIC COMPONENT, AND MANUFACTURING A DISPLAY

(71) Applicant: Stroke Precision Advanced Engineering Co., Ltd., Taoyuan City (TW)

(72) Inventor: Chingju Lin, Taoyuan City (TW)

(73) Assignee: Stroke Precision Advanced Engineering Co., Ltd., Taoyuan City (TW)

(21) Appl. No.: 18/639,981

(22) Filed: Apr. 19, 2024

(30) Foreign Application Priority Data
Jul. 10, 2023 (TW) 112125716

(51) Int. Cl. H01L 23/00; H01L 25/16

(52) U.S. Cl. CPC H01L 24/75; H01L 24/81; H01L 25/167; H01L 2224/75263; H01L 2224/753; H01L 2224/81201; H01L 2224/81224; H01L 2224/81815; H01L 2924/12041; H01L 2924/1426

(57) ABSTRACT

A device configured to partially flatten a substrate includes a carrying platform and a pressing airflow generator. The carrying platform has a carrying plane and is configured to carry the substrate to be flattened on the carrying plane. The pressing airflow generator includes a body having an airflow guiding channel disposed thereon, an actuator capable of driving the body to move along the carrying plane relative to the carrying platform, and an air pump capable of providing an airflow to the airflow guiding channel of the body. The airflow guiding channel can guide the airflow to lift up the body from the carrying platform, thereby creating a pressing airflow between the body and the carrying platform. An apparatus configured to bond an electronic component and methods for bonding an electronic component and manufacturing a light-emitting diode display are also provided.

### CROSS-REFERENCE TO RELATED APPLICATION

This application claims the priority benefit of Taiwan application serial no. 112125716, filed on Jul. 10, 2023. The entirety of the above-mentioned patent application is hereby incorporated by reference herein and made a part of this specification.

### BACKGROUND

### Technical Field

The disclosure relates to a device configured to partially flatten a substrate, an apparatus configured to bond an electronic component, a method for bonding an electronic component, and a method for manufacturing a light-emitting diode display.

### Description of Related Art

With the development of the manufacturing process of electronic components (such as micro electronic components, light emitting diodes, or micro light emitting diodes), a process for mass transfer of the electronic components, the light emitting diodes, or the micro light emitting diodes from one substrate to another substrate has been developed to facilitate mass manufacturing of the electronic components.

However, in the process of transferring the electronic components, the light-emitting diodes, or the micro-light-emitting diodes from one substrate to another, it is necessary to configure the two substrates face to face, and then use a laser processing method to transfer the electronic components, the light-emitting diodes, or micro light-emitting diodes. At this time, whether the two substrates are bonded to each other and whether the substrate remains flat during laser processing is crucial to the yield of the transfer process.

### SUMMARY

An embodiment of the disclosure provides a device configured to partially flatten a substrate, which includes a carrying platform and a pressing airflow generator. The carrying platform has a carrying plane and is configured to carry a substrate to be flattened on the carrying plane. The pressing airflow generator includes a body, an actuator, and an air pump. The body has an airflow guiding channel disposed thereon. The actuator can drive the body to move along the carrying plane relative to the carrying platform. The air pump can provide an airflow to the airflow guiding channel of the body. The airflow guiding channel can guide the airflow to lift up the body from the carrying platform, thereby creating a pressing airflow between the body and the carrying platform.

An embodiment of the disclosure provides an apparatus configured to bond an electronic component, which includes the device configured to partially flatten the substrate and an energy generator. The energy generator is disposed near the carrying platform of the device configured to partially flatten the substrate, and configured to generate an energy beam that travels toward the carrying platform through the pressing airflow.

An embodiment of the disclosure provides a method for bonding an electronic component, which includes the following steps. A transfer substrate is provided, where the electronic component to be bonded is disposed on a surface of the transfer substrate. A target substrate is provided, where the target substrate includes a bonded surface. The bonded surface of the target substrate is configured to face the surface of the transfer substrate on which the electronic component to be bonded is disposed, and the electronic component to be bonded is configured to be in contact with the bonded surface of the target substrate. A pressing airflow is applied onto a surface in opposition to the surface of the transfer substrate on which the electronic component to be bonded is disposed or onto the surface of the target substrate in opposition to the bonded surface. An energy beam is applied through the pressing airflow to bond the electronic component to be bonded onto the target substrate from the transfer substrate.

An embodiment of the disclosure provides a method for manufacturing a light-emitting diode display, which includes bonding a light-emitting diode chip using the above-mentioned method for bonding the electronic component.

### BRIEF DESCRIPTION OF THE DRAWINGS

FIG. 1 is a schematic cross-sectional view of an apparatus configured to bond an electronic component according to an embodiment of the disclosure.

FIG. 2 is a schematic top view of a movement path of the energy generator in FIG. 1 relative to the carrying platform.

FIG. 3A and FIG. 3B are schematic cross-sectional views of two steps in a process of a method for bonding an electronic component according to an embodiment of the disclosure.

### DESCRIPTION OF THE EMBODIMENTS

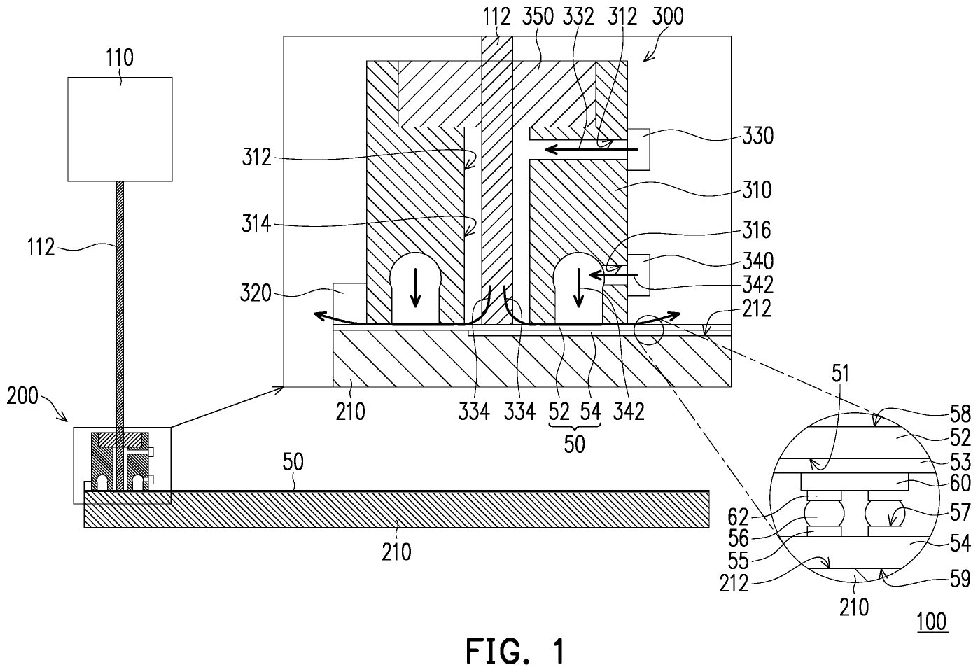

FIG. 1 is a schematic cross-sectional view of an apparatus configured to bond an electronic component according to an embodiment of the disclosure. Referring to FIG. 1, an apparatus 100 configured to bond an electronic component provided in the embodiment includes a device 200 configured to partially flatten a substrate and an energy generator 110. The device 200 configured to partially flatten the substrate includes a carrying platform 210 and a pressing airflow generator 300. The carrying platform 210 has a carrying plane 212. In the embodiment, the carrying plane 212 is, for example, an upper surface of the carrying platform 210. The carrying platform 210 is configured to carry a substrate 50 to be flattened on the carrying plane 212. In the embodiment, the substrate 50 to be flattened includes a combination of a transfer substrate 52 which carries an electronic component 60 to be bonded and a target substrate 54. In an embodiment, the transfer substrate 52 is, for example, a temporary substrate, and the target substrate 54 is, for example, a circuit substrate. In the embodiment, there are a plurality of electronic components 60 to be bonded on the transfer substrate 52, and the enlarged view of FIG. 1 shows one of the electronic components 60 as an example.

The pressing airflow generator 300 includes a body 310, a driver 320, and an air pump 330. The body 310 has an airflow guiding channel 312 disposed thereon. The driver 320 can drive the body 310 to move along the carrying plane 212 relative to the carrying platform 210. For example, the driver 320 can drive the carrying platform 210 or the body 310 such that the body 310 moves along the carrying plane 212 relative to the carrying platform 210. In the embodiment, the driver 320 is, for example, a motor or other appropriate actuators.

The air pump 330 can provide an airflow 332 to the airflow guiding channel 312 of the body 310. The airflow guiding channel 312 can guide the airflow 332 provided by the air pump 330 to be between the body 310 and the carrying platform 210 so as to lift up the body 310 and generate a pressing airflow 334 between the body 310 and the carrying platform 210.

The energy generator 110 is disposed near the carrying platform 210 of the device 200 configured to partially flatten the substrate, and configured to generate an energy beam 112 that penetrates the pressing airflow and emits toward the carrying platform 210. In the embodiment, the energy beam 112 is a laser beam, and the energy generator 110 is, for example, a laser light source. In addition, in the embodiment, the body 310 includes a light channel 314 penetrating therethrough. The light channel 314 can guide the energy beam 112 generated by the energy generator 110 toward the pressing airflow 334 and the carrying platform 210. In the embodiment, a light-transmitting plate 350 (such as a quartz plate) may be disposed on the top of the body 310 (i.e., the top of the light channel 314), and the energy beam 112 penetrates the light-transmitting plate 350 and enters the light channel 314. The light-transmitting plate 350 can seal the top of the airflow guiding channel 312 to facilitate the generation of the pressing airflow 334.

In an embodiment, the electronic component 60 to be bonded can be attached to the transfer substrate 52 through an adhesive layer 53, and the electronic component 60 has electrodes 62. In addition, the target substrate 54 has pads 55, and solder 56 can be disposed on the pads 55. The energy beam 112 can be irradiated on the solder 56 to melt the solder 56. At this time, the electrodes 62 are aligned with the pads 55, so when the solder 56 cools and solidifies, the electrodes 62 and the pads 55 can be bonded. At this time, the bonding force between the solder 56 and the electrodes 62 is greater than the adhesion force between the adhesive layer 53 and the electronic component 60. Therefore, when the transfer substrate 52 and the target substrate 54 are separated, the electronic component 60 will remain on the target substrate 54 and be separated from the transfer substrate 52. In this way, the electronic component 60 can be transferred from the transfer substrate 52 to the target substrate 54. In the embodiment, the electronic component 60 to be bonded is, for example, a light-emitting diode chip or other electronic components.

In the device 200 configured to partially flatten the substrate and the apparatus 100 configured to bond the electronic component provided in the embodiment, the pressing airflow generator 300 uses the air pump 330 to provide the airflow 332 to the airflow guiding channel 312 of the body 310, and the airflow guiding channel 312 can guide the airflow 332 provided by the air pump 330 to be between the body 310 and the carrying platform 210 so as to lift up the body 310 and generate the pressing airflow 334 between the body 310 and the carrying platform 210, so that the substrate 50 can be flattened. In this way, when the energy beam 112 is used for processing, the transfer substrate 52 can be attached to the target substrate 54 closely, thereby effectively improving the process yield. In addition, the body 310 is lifted up on the carrying platform 210 to achieve a local pressure equalization effect, thereby improving the yield of the transferred electronic component 60.

In the embodiment, the body 310 may include another airflow guiding channel 316 and another air pump 340. The airflow guiding channel 316 is next to the airflow guiding channel 312 and will not be penetrated by the energy beam 112. The air pump 340 can provide an airflow 342, and the airflow 342 can be guided and applied on the substrate 50 or the carrying platform 210 to increase the effect of lifting up the body 310. However, in other embodiments, the body 310 may not include the airflow guiding channel 316 and the air pump 340.

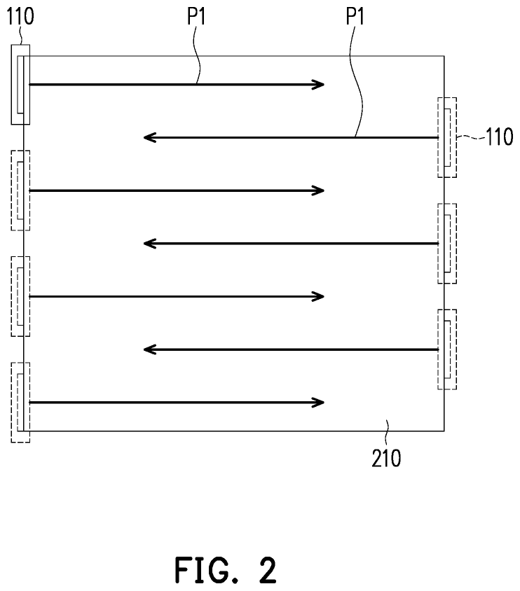

FIG. 2 is a schematic top view of a movement path of the energy generator in FIG. 1 relative to the carrying platform. Referring to FIG. 1 and FIG. 2, the energy generator 110 can move relative to the carrying platform 210. At this time, the body 310 also moves with the energy generator 110 relative to the carrying platform 210, so that the energy beam 112 can sequentially process the plurality of electronic components 60 on the substrate 50, for example, according to a path Pl shown in FIG. 2. In an embodiment, the carrying platform 210 can move relative to the energy generator 110. In the embodiment, the light-transmitting plate 350 (such as a quartz plate) only occupies a small part of the area of the carrying platform 210 instead of covering most of the area of the carrying platform 210, so costs can be effectively reduced and there is less risk of breakage of the quartz plate.

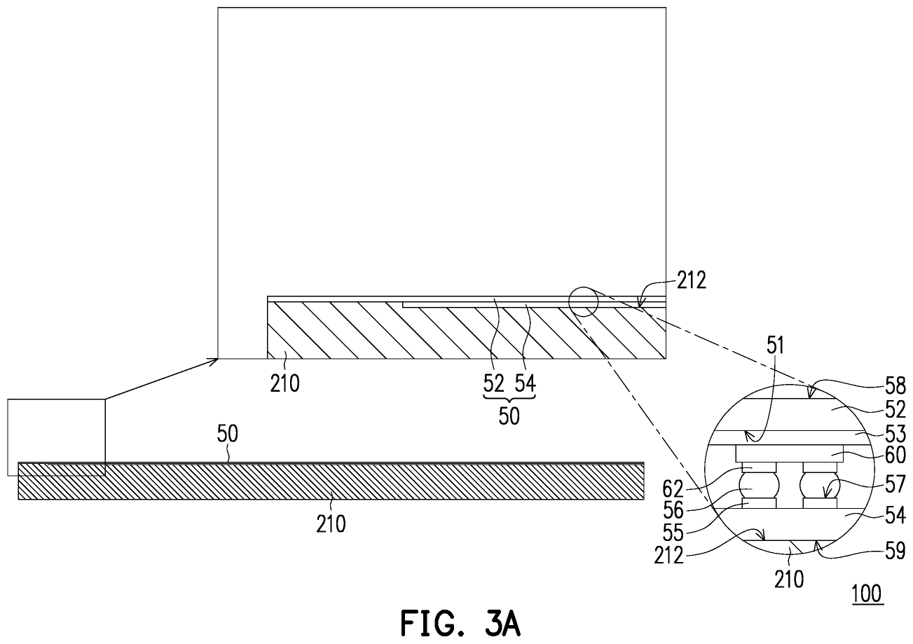

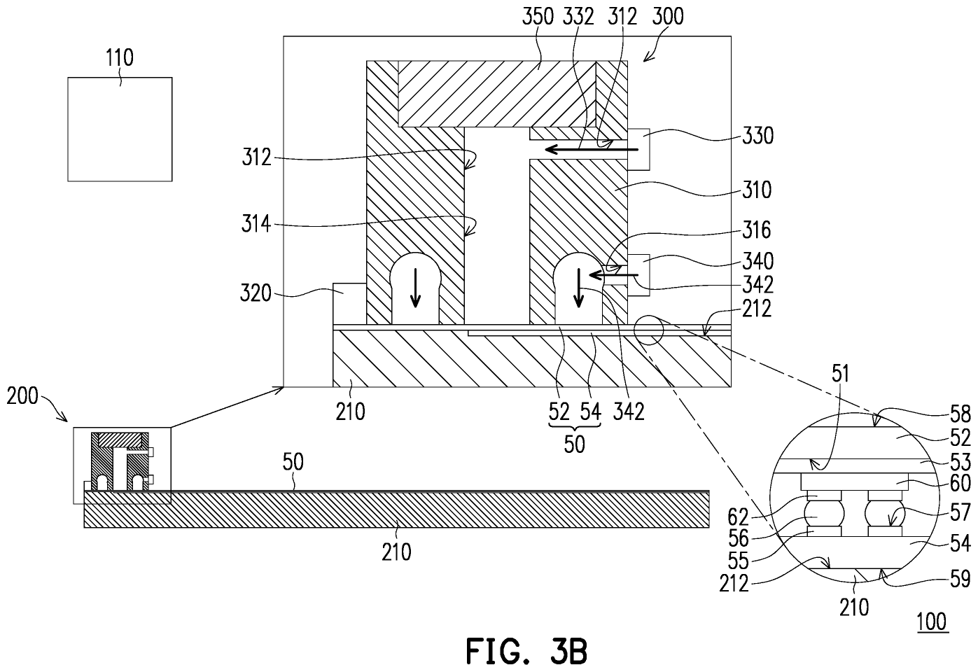

FIG. 3A and FIG. 3B are schematic cross-sectional views of two steps in a process of a method for bonding an electronic component according to an embodiment of the disclosure. Referring to FIG. 3A, FIG. 3B, and FIG. 1, the method for bonding the electronic component provided in the embodiment can be performed by using the apparatus configured to bond the electronic component in FIG. 1, but the disclosure is not limited thereto. The method for bonding the electronic component provided in the embodiment includes the following steps. First, as shown in FIG. 3A, the transfer substrate 52 is provided, where the electronic component 60 to be bonded is disposed on a surface 51 of the transfer substrate 52. Furthermore, the target substrate 54 is provided, where the target substrate 54 includes a bonded surface 57. Then, the bonded surface 57 of the target substrate 54 is configured to face the surface 51 of the transfer substrate 52 on which the electronic component 60 to be bonded is disposed, and the electronic component 60 to be bonded is configured to be in contact with the bonded surface 57 of the target substrate 54.

Next, as shown in FIG. 3B, the pressing airflow 334 is applied to a position at a surface 58 of the transfer substrate 52 on which the electronic component 60 to be bonded is not disposed (at this time, the transfer substrate 52 is disposed between the target substrate 54 and the body 310) or at a surface 59 of the target substrate 54 opposite to the bonded surface 57 (at this time, the target substrate 54 is disposed between the transfer substrate 52 and the body 310), and opposite to a position of the electronic component 60 to be bonded. After that, as shown in FIG. 1, the energy beam 112 is applied through the pressing airflow 334 to bond the electronic component 60 to be bonded onto the target substrate 54 from the transfer substrate 52.

In the embodiment, the pressing airflow 334 is generated by lifting up the body 310 through an airflow generated between the body 310 and the transfer substrate 52 (at this time, the transfer substrate 52 is disposed between the target substrate 54 and the body 310) or the target substrate 54 (at this time, the target substrate 54 is disposed between the transfer substrate 52 and the body 310). In addition, the energy beam 112 is applied to the transfer substrate 52 or the target substrate 54 through the pressing airflow 334, such as being applied to the solder 56 on the transfer substrate 52, or applied to the solder 56 on the target substrate 54. That is, the solder 56 may be disposed on the transfer substrate 52 or the target substrate 54.

After the solder 56 is melted by the energy beam 112 and cooled and solidified, the solder 56 can bond the electrodes 62 and the pads 55. At this time, the bonding force between the solder 56 and the electrodes 62 is greater than the adhesion force between the adhesive layer 53 and the electronic component 60. Therefore, when the transfer substrate 52 and the target substrate 54 are separated, the electronic component 60 will remain on the target substrate 54 and be separated from the transfer substrate 52. In this way, the electronic component 60 can be transferred from the transfer substrate 52 to the target substrate 54. An embodiment of the disclosure provides a method for manufacturing a light-emitting diode (LED) display, which may include bonding a light-emitting diode chip using the above-mentioned method for bonding the electronic component. In the method for manufacturing the light-emitting diode display, the target substrate 54 is, for example, a display backplane, such as a thin film transistor (TFT) substrate, and the electronic component 60 is a light-emitting diode chip, such as a micro light-emitting diode chip. In this way, after the transfer substrate 52 and the target substrate 54 are separated, the electronic component 60 (the light-emitting diode) remain on the target substrate 54 (the display backplane) to form the light-emitting diode display.

In the method for bonding the electronic component and the method for manufacturing the light-emitting diode display provided in the embodiment, since the pressing airflow 334 is applied to a position at the surface 58 of the transfer substrate 52 on which the electronic component 60 to be bonded is not disposed or at the surface 59 of the target substrate 54 opposite to the bonded surface 57, and opposite to the position of the electronic component 60 to be bonded, the transfer substrate 52 and the target substrate 54 can be closely attached when the energy beam 112 is applied, thereby effectively improving the process yield.

In summary, in the device configured to partially flatten the substrate and the apparatus configured to bond the electronic component according to the embodiments of the disclosure, the pressing airflow generator uses the air pump to provide the airflow to the airflow guiding channel of the body, and the airflow guiding channel can guide the airflow to lift up the body from the carrying platform, thereby creating a pressing airflow between the body and the carrying platform, and flattening the substrate and effectively improving the process yield. In the method for bonding the electronic component and the method for manufacturing the light-emitting diode display according to the embodiments of the disclosure, since the pressing airflow is applied to a position at the surface of the transfer substrate on which the electronic component to be bonded is not disposed or at the surface of the target substrate opposite to the bonded surface, and opposite to the position of the electronic component to be bonded. the transfer substrate and the target substrate can be closely attached when the energy beam is applied, thereby effectively improving the process yield.

What is claimed is:

1. An apparatus configured to bond an electronic component, comprising:
a carrying platform having a carrying plane, wherein the carrying platform is configured to load substrates which carry the electronic component to be bonded;
a pressing airflow generator, comprising:
a body having an airflow guiding channel disposed therein;
an actuator configured to drive the body to move relative to the carrying platform and along the carrying plane; and
an air pump configured to provide an airflow into the airflow guiding channel;
wherein the airflow guiding channel guides the airflow to lift up the body from the carrying platform, thereby creating a pressing airflow between the body and the carrying platform; and
an energy generator configured to generate an energy beam traveling toward the carrying platform and through the pressing airflow.

2. The apparatus configured to bond an electronic component according to claim 1, wherein the energy beam is a laser beam.

3. The apparatus configured to bond an electronic component according to claim 1, wherein the body comprises a light channel penetrating therethrough, and the light channel guides the energy beam toward the pressing airflow and the carrying platform.

4. The apparatus configured to bond an electronic component according to claim 1, wherein the substrates comprise a combination of a transfer substrate which carries the electronic component to be bonded and a target substrate.

5. A method for bonding an electronic component, comprising:
providing a transfer substrate having a surface on which the electronic component to be bonded is disposed;
providing a target substrate having a bonded surface;
configuring the bonded surface of the target substrate to face the surface of the transfer substrate on which the electronic component to be bonded is disposed, with making the electronic component to be bonded in contact with the bonded surface of the target substrate;
applying a pressing airflow onto a surface in opposition to the surface of the transfer substrate on which the electronic component to be bonded is disposed or onto a surface of the target substrate in opposition to the bonded surface, and
applying an energy beam through the pressing airflow to bond the electronic component onto the target substrate from the transfer substrate.

6. The method for bonding an electronic component according to claim 5, wherein the pressing airflow is generated by lifting up a body via an airflow over the transfer substrate or over the target substrate.

7. The method for bonding an electronic component according to claim 5, wherein the energy beam is applied to the transfer substrate through the pressing airflow.

8. The method for bonding an electronic component according to claim 5, wherein the energy beam is a laser beam.

9. The method for bonding an electronic component according to claim 5, wherein the electronic component to be bonded is a light-emitting diode (LED) chip.

10. A method for manufacturing an LED display, comprising bonding an LED chip onto a target substrate using the method for bonding an electronic component according to claim 9.

11. The method for manufacturing an LED display according to claim 10, wherein the target substrate is a thin film transistor (TFT) substrate.
